(19) United States
(12) Patent Application Publication
(10) Pub. No.: US 2024/0328029 A1
(43) Pub. Date: Oct. 3, 2024

(54) METHOD FOR PRODUCING SILICON SINGLE CRYSTAL

(71) Applicant: SHIN-ETSU HANDOTAI CO., LTD., Tokyo (JP)

(72) Inventor: Keisuke MIHARA, Nishigo-mura (JP)

(73) Assignee: SHIN-ETSU HANDOTAI CO., LTD., Tokyo (JP)

(21) Appl. No.: 18/576,638

(22) PCT Filed: Jul. 28, 2022
(86) PCT No.: PCT/JP2022/029046

§ 371 Date: Jan. 4, 2024

(30) Foreign Application Priority Data
Jul. 29, 2021 (JP) 2021-124122

(51) Int. Cl. C30B 15/22; C30B 29/06; C30B 30/04

(52) U.S. Cl. CPC C30B 15/22; C30B 29/06; C30B 30/04

(57) ABSTRACT

The present invention provides a method for producing a silicon single crystal by a CZ method using a cusp magnetic field formed by an upper coil and a lower coil provided in a pulling furnace, the method includes seeding by bringing a seed crystal into contact with a silicon melt, and pulling up of a straight body after enlarging a diameter of the silicon single crystal, in which the seeding is performed with a magnetic field minimum plane position on a central axis of the pulling furnace as a first position below a surface of the silicon melt, before proceeding to the pulling up of the straight body, the magnetic field minimum plane position on the central axis of the pulling furnace is moved to a second position above the first position, the pulling up of the straight body is performed with the magnetic field minimum plane position on the central axis of the pulling furnace as the second position. This provides the method for producing the silicon single crystal that efficiently produces the single crystal having low oxygen concentration and excellent in-plane distribution with an improved success rate of the seeding.

### TECHNICAL FIELD

The present invention relates to a method for producing a silicon single crystal by a CZ method using a cusp magnetic field.

### BACKGROUND ART

In recent years, power devices have been attracting attention as devices to realize power saving. A region where an electric current flows in the power device may be in the thickness range of approximately tens or hundreds of micrometers from a surface layer, or in some cases, the electric current flows an entire wafer. When an oxygen precipitate or a Bulk Micro Defect (BMD) exists in the region where this electric current flows, breakdown voltage failure or leakage defect may occur. To prevent the above defects, silicon single crystal wafers for power devices are required to have a low oxygen concentration to the extent that oxygen precipitate is not produced, and a flat in-plane distribution of oxygen and resistivity.

A Czochralski (CZ) method is one of the leading methods for producing a silicon single crystal for the power device. In the CZ method, the silicon single crystal is grown by bringing a seed crystal into contact with a heated silicon melt and gradually pulling the seed crystal up above the melt. Suppose the seed crystal and the silicon melt have a significant temperature difference, heat shock occurs when the seed crystal contacts the silicon melt, and due to this heat shock, slip dislocation is generated. The method to remove the slip dislocation, which is generated when the seed crystal is brought into contact with the silicon melt, by narrowing the crystal diameter to 3 to 5 mm is called a Dash Necking method and has been widely used in the production of the silicon single crystal using the CZ method.

Recently, as the silicon single crystal having a larger diameter and heavier weight has been developed, a dislocation-free seeding method that does not use the Dash Necking method disclosed in Patent Document 1 has also been implemented. According to the method of Patent Document 1, a seed crystal with a shape of a pointed tip in which an angle of the tip is 28° or less is used, and the seed crystal described above is heated to nearly the same temperature as the raw material melt before contacting the silicon melt, and then the seed crystal is brought into contact into the silicon melt, consequently, incurring heat shock can be suppressed. Using this method to grow a single crystal enables efficient production of a large-diameter and heavy single crystal with a diameter of 300 mm or more.

### CITATION LIST

### Patent Literature

Patent Document 1: JP 4151580 B2
Patent Document 2: JP 2009-18984 A
Patent Document 3: WO 2009/025340
Patent Document 4: JP 2001-89289 A
Patent Document 5: JP 2020-33200 A

### SUMMARY OF INVENTION

### Technical Problem

In the case of producing a silicon single crystal by a CZ method, using a Magnetic field applied Czochralski (MCZ) method is mainstream in which a single crystal is pulled while a magnetic field is applied to a raw material melt. As a growth method of a low-oxygen crystal for a power device, a method using a horizontal magnetic field and a method using a cusp magnetic field are known.

As a method using a horizontal magnetic field, for example, Patent Document 2 discloses a method for obtaining the low-oxygen crystal by specifying the crystal rotational rate and crucible rotational rate under a horizontal magnetic field. Still, this method targets a diameter of 200 mm and is not applicable to the growth of a silicon single crystal with a large diameter of 300 mm or larger. In addition, as disclosed in Patent Document 3, there is a method of defining an intensity of the magnetic field to 2000 G or more and defining a rotational rate of the crystal to 5 rpm or less. This method performs doping with hydrogen at the production of the single crystal and neutron irradiation after the production of the single crystal. However, it is problematic that performing these processes increases the costs of producing the crystal. In addition, to produce the low-oxygen crystal with a diameter of 300 mm or more in the horizontal magnetic field, making a crystal rotational rate low, as disclosed in Patent Document 3, is needed. However, making the crystal rotation rate low deteriorates an in-plane distribution of resistivity and oxygen, causing a problem of device defects.

On the other hand, as disclosed in Patent Document 4, for example, as a method using the cusp magnetic field, a method exists to move a central position of the magnetic field of the cusp magnetic field (magnetic field minimum plane position) depending on the amount of reduced silicon melt to a position where a temperature is stabilized. In this method, along with a rise in a solidification ratio of the single crystal, the magnetic field minimum plane position of the cusp magnetic field is elevated. A change in the magnetic field minimum plane position within the product portion (straight body portion) causes an increase in the amount of change in oxygen concentration in the product portion, resulting in a problem in which yield is significantly reduced when the crystal with a narrow specification range of the oxygen concentration or the low-oxygen crystal is produced.

Moreover, as disclosed in Patent Document 5, a method is present where a crystal rotating rate, a crucible rotating rate, the central position of the magnetic field (magnetic field minimum plane position), and the intensity of the magnetic field are specified, thereby obtaining the low-oxygen crystal. By this means, the magnetic field minimum plane position is positioned close to a solid-liquid interface, and besides, the intensity of the magnetic field being defined from 500 to 700 G can obtain the single crystal having a low oxygen concentration of 4×10¹⁷ atoms/cm³ or lower. As described above, to produce a large-diameter and heavy single crystal with a diameter of 300 mm or more, the dislocation-free seeding method is preferable without a Dash Necking method. However, under the conditions disclosed in Patent Document 5, a temperature variation on a raw material melt surface at seeding is significant, and this causes a problem in which a success of the seeding becomes difficult; thus, the productivity of the single crystal is decreased.

The present invention has been made in view of the above-described problem. An object of the present invention is to provide a method for producing a silicon single crystal to produce a single crystal with a lower oxygen concentration and better in-plane distribution with an improved seeding success rate and production efficiency than a prior art.

### Solution to Problem

To achieve the object, the present invention provides a method for producing a silicon single crystal by a CZ method using a cusp magnetic field formed by an upper coil and a lower coil provided in a pulling furnace, the method comprising the steps of:
seeding by bringing a seed crystal into contact with a silicon melt; and
pulling up of a straight body after enlarging a diameter of the silicon single crystal, wherein
the seeding is performed with a magnetic field minimum plane position on a central axis of the pulling furnace as a first position below a surface of the silicon melt,
before proceeding to the pulling up of the straight body, the magnetic field minimum plane position on the central axis of the pulling furnace is moved to a second position above the first position,
the pulling up of the straight body is performed with the magnetic field minimum plane position on the central axis of the pulling furnace as the second position.

With the method for producing the silicon single crystal like this, a variation of the surface temperature of a raw material melt (silicon melt) during seeding becomes small, thus, the success rate of the seeding is significantly improved. In addition, at the pulling of the straight body of a product portion, oxygen tends to be easily incorporated from a low-oxygen layer on a silicon melt surface into a single crystal by changing a magnetic field minimum plane position thus, the silicon single crystal with a low oxygen concentration and an excellent in-plane distribution can be produced. As a result of a combination of these effects, the single crystal with the low oxygen concentration and the excellent in-plane distribution can be efficiently produced.

In this case, the first position can be between 30 mm to 80 mm below the surface of the silicon melt, and the second position is between 10 mm below and 100 mm above the surface of the silicon melt.

This enables more stable and reliable production of the silicon single crystal with the low oxygen concentration and the excellent in-plane distribution with an improved seeding success rate and production efficiency.

In this case, at the seeding, an intensity of the magnetic field at an intersection of an intermediate plane between the upper coil and the lower coil and an inner wall of a crucible can be 1500 G or more.

This enables a more stable and reliable improvement of the seeding success rate and the production efficiency.

In this case, at the pulling up of the straight body, an intensity of a magnetic field at an intersection of an intermediate plane between the upper coil and the lower coil and an inner wall of a crucible can be 750 G or more and 1800 G or less.

This enables more stable and reliable production of the silicon single crystal with the low oxygen concentration and the excellent in-plane distribution.

In this case, the seeding can be performed by a dislocation-free seeding method.

This enables the efficient production of the silicon single crystal with a stable low oxygen concentration and the excellent in-plane distribution, even for a larger diameter silicon single crystal, with an improved seeding success rate.

In this case, after the seeding, a necking can be performed while the magnetic field minimum plane position on the central axis of the pulling furnace is the first position below the surface of the silicon melt.

Thus, even when the Dash Necking method is performed, the silicon single crystal with the stable low oxygen concentration and the excellent in-plane distribution can be efficiently produced while improving the seeding success rate.

### Advantageous Effects of Invention

As described above, the inventive method for producing the silicon single crystal can improve the success rate of seeding by reducing temperature variation on the surface of silicon melt at seeding. Additionally, the method can efficiently produce the single crystal having the low oxygen concentration and the excellent in-plane distribution that satisfies a required quality for such as a power device at a straight body portion.

### BRIEF DESCRIPTION OF DRAWINGS

FIG. 1 is a view illustrating an example of a single crystal pulling apparatus.

### DESCRIPTION OF EMBODIMENTS

Hereinafter, the present invention will be described in detail. However, the present invention is not limited thereto.

As described above, in recent years, the quality of a low-oxygen crystal used for a power device, etc. is required to have a higher level than a conventional level. Especially, a desirable oxygen concentration is supposed to be 3×10¹⁷ atoms/cm³ (ASTM'79) or lower to remove an effect of a thermal donor generated by a low-temperature heat treatment. In addition, an in-plane distribution of oxygen concentration is desirably uniform to eliminate a chip-to-chip variation in quality. For example, when the oxygen concentration in a periphery side of a wafer is low, slip dislocations may occur during heat treatment, which in some cases adversely affects a yield of a device process. In response to this case, impurity doping, such as nitrogen doping, can increase the strength, but since nitrogen also affects the formation of a defect and a donor, making the in-plane oxygen concentration uniform as a measure not to depend on the doping is important.

Moreover, Radial Oxygen Gradient (ROG) can be used as an indicator to measure an excellence of in-plane distribution of oxygen. ROG is a value obtainable by measuring the oxygen concentration in at least two locations: a wafer center and a position of 5 mm from the wafer periphery, and using a formula: (maximum value−minimum value)×100/maximum value. In recent years, a higher level of ROG than the conventional level has been required, and an excellent distribution in which ROG satisfies to be less than 15% is required.

Incidentally, a silicon melt is accommodated in a quartz crucible in a CZ method, and oxygen is incorporated into a silicon single crystal by elution of an oxygen component from the quartz crucible into the silicon melt during a crystal pulling. When a surface layer of the silicon melt surface is viewed down from the vertical direction in the MCZ method using the horizontal magnetic field, convection is suppressed in the direction parallel to the magnetic field lines because the magnetic field affects this direction. Still, convection is activated in the direction vertical to the magnetic field lines because almost no magnetic field affects this direction. Thus, the region where the convection is locally active is formed, and the oxygen component becomes easier to elute from the quartz crucible in the horizontal magnetic field, as a result, enriching a high oxygen concentration of the silicon single crystal.

On the other hand, in the case of a cusp magnetic field, the magnet field affects a vicinity of an inner wall of the crucible in an entire circumference; thus, convection in the vicinity of the inner wall of the crucible is suppressed in the entire circumference. Consequently, in a cusp magnetic field, when a rotational rate of the crucible is sufficiently fast, and an intensity of the magnetic field turns into a high magnetic field, then the relative velocity between the quartz crucible and the silicon melt becomes high. Then, the elution of the oxygen component is facilitated. On the contrary, when the rotational rate of the crucible is sufficiently low, and the intensity of the magnetic field turns into a low magnetic field, then the relative velocity between the quartz crucible and the silicon melt becomes slow. Then, the elution of oxygen is suppressed. In addition to the factors described above, by defining the magnetic field minimum plane position in the cusp magnetic field close to a condition of a solid-liquid interface of the single crystal or a position above, natural convection inherent to the cusp magnetic field facilitates the incorporation of the oxygen components into the single crystal from a layer of the low oxygen concentration on the silicon melt surface. Therefore, the present inventor found out that by using the cusp magnetic field and defining the magnetic field minimum plane position to a position close to the solid-liquid interface of the single crystal or above the position of, an improvement of low oxygenation and uniformity of the crystal can be realized.

In addition to the described above, to produce a low-oxygen crystal that meets all required qualities for the power device with high productivity, improvement of a success rate of the seeding is needed. The present inventor has earnestly studied and found out that if the seeding is performed while the magnetic field minimum plane position of the cusp magnetic field is defined at a position close to or above the solid-liquid interface similar to the condition for the product portion described above, a temperature variation on the silicon melt surface increases, consequently, the success rate of the seeding is significantly dropped, and productivity of the crystal is lowered.

Therefore, the present inventor has conceived a method for producing a silicon single crystal by a CZ method using a cusp magnetic field in which seeding is performed while a magnetic field minimum plane position on the central axis of a pulling furnace is below a surface of the silicon melt (raw material melt), then before proceeding to a product portion of pulling up of a straight body, the magnetic field minimum plane position is moved upward, and then the pulling up of the straight body of the product portion is performed.

That is to say, to solve the above problem, the present inventors have earnestly studied and found a method for producing a silicon single crystal by a CZ method using a cusp magnetic field formed by an upper coil and a lower coil provided in a pulling furnace, the method includes: seeding by bringing a seed crystal into contact with a silicon melt, and pulling up of a straight body after enlarging a diameter of the silicon single crystal, in which the seeding is performed with a magnetic field minimum plane position on a central axis of the pulling furnace as a first position below a surface of the silicon melt, before proceeding to the pulling up of the straight body, the magnetic field minimum plane position on the central axis of the pulling furnace is moved to a second position above the first position, the pulling up of the straight body is performed with the magnetic field minimum plane position on the central axis of the pulling furnace as the second position, and thus an efficient production of the single crystal with the low oxygen concentration and excellent in-plane distribution is enabled. Based on this finding, the present invention has been completed.

Hereinafter, a description is given referring to the drawings.

### [Single Crystal Pulling Apparatus]

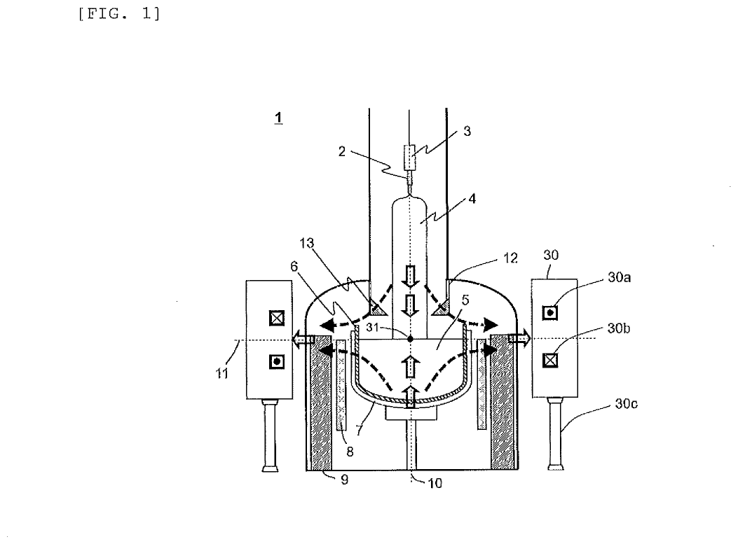

Firstly, a single crystal pulling apparatus suitably used for the inventive method for producing a silicon single crystal is described. FIG. 1 shows one example of the single crystal pulling apparatus. A single crystal pulling furnace 1 shown in FIG. 1 is configured to have a heat-insulating material 9, a heater 8 inside of the heat-insulating material 9, and a heat shielding member 13 facing a silicon melt 5 (raw material melt) accommodated in a quartz crucible 6 in a graphite crucible 7 at a lower end of a cylindrical part 12. Moreover, a magnetic field generator 30, having an upper coil 30a and a lower coil 30b, being two upper and lower superconducting coils, is installed in the surrounding area, and the cusp magnetic field is applied to the silicon melt 5 by energizing the upper coil 30a and the lower coil 30b. A seed crystal 2 held by a seed holder 3 connected to a wire on a central axis 10 of the pulling furnace 1 is brought in contact with the silicon melt 5, thereby performing seeding. Then, a diameter of the silicon single crystal is enlarged. Then, a silicon single crystal 4 is produced by configuration to pull a straight body portion to be a product portion toward a pulling direction.

The magnetic field generator 30 is installed on an elevating device 30c, which is movable up and down to the vertical direction and provided with the upper coil 30a and the lower coil 30b. The cusp magnetic field is generated by applying electric currents in opposite directions to two upper and lower coils. If the electric current values of the upper coil 30a and the lower coil 30b are the same values and the electric current passes in opposite directions, the magnetic field distribution is symmetrical from the top to the bottom direction and from the left to the right direction. In this case, an intensity of the magnetic field at a magnetic field minimum plane position 31 at an intersection of a central axis 10 and an intermediate plane 11 between the upper and the lower coils is 0 gauss.

Moreover, when the electric current values of the upper coil 30a and the lower coil 30b are defined differently from each other, and by applying electric currents in opposite directions to two upper and lower coils, the magnetic field distribution becomes asymmetrical from top to bottom and symmetrical from left to right, and the magnetic field minimum plane position 31 changes compared to the case where the electric current values of the upper and lower coil are the same values (hereafter referred to as “unbalanced excitation”). For example, when the electric current value of the upper coil>the electric current value of the lower coil, the magnetic field minimum plane position 31 moves to a lower side compared to the case where the electric current values of the upper and the lower coils are defined to the same value, and when the electric current value of the upper coil<the electric current value of the lower coil, the magnetic field minimum plane position 31 moves to an upper side compared to the case where the electric current values of the upper and lower coils are defined to the same value.

Incidentally, a structure such as HZ (Hot Zone), other than that described above, can be a similar structure to a conventional method for a silicon single crystal producing apparatus by CZ.

### [Method for Producing Silicon Single Crystal]

Then, the inventive method for producing a silicon single crystal is described. The inventive method for the silicon single crystal includes seeding by bringing a seed crystal into contact with a silicon melt, and pulling up a straight body after enlarging a diameter of the silicon single crystal. The seeding is performed with a magnetic field minimum plane position on a central axis of the pulling furnace as a first position below a surface of the silicon melt, before proceeding to the pulling up of the straight body, the magnetic field minimum plane position on the central axis of the pulling furnace is moved to a second position above the first position, the pulling up of the straight body is performed with the magnetic field minimum plane position on the central axis of the pulling furnace as the second position. Hereinafter, a description will be given in detail.

### (Seeding)

At seeding, necking is performed with a magnetic field minimum plane position 31 on a central axis 10 of the single crystal pulling furnace 1 as a first position, below a surface of the silicon melt 5 (raw material melt). In this case, a seed crystal 2 is preferably heated directly above a silicon melt 5 for about 5 to 60 minutes before the seeding. Performing this heating reduces a temperature difference between the seed crystal 2 and the silicon melt 5, as a result, when the melt and the seed crystal come into contact with each other, a heat shock can be mitigated. Consequently, a success rate of pulling the silicon single crystal with dislocation-free is further improved, and thus, productivity can be improved.

During the seeding, a first position of the magnetic field minimum plane position of a cusp magnetic field is preferably below the surface of the silicon melt of between 30 mm to 80 mm (30 mm or more and 80 mm or less). Such a range makes seeding more stable and further improves the success rate.

Moreover, as described above, in the MCZ method, magnetic field distribution and the intensity of the magnetic field near an inner wall of the crucible are factors that determine the amount of oxygen component incorporated into the single crystal. Thus, specifying these conditions is preferred to produce a low-oxygen crystal with high productivity. Consequently, the inventive method for producing the silicon single crystal determines the intensity of the magnetic field according to a value at the intersection of the intermediate plane between the upper coil and the lower coil (between the upper and lower coils) and the inner wall of the crucible.

At the seeding in the inventive method for producing the silicon single crystal, necking is preferably performed after applying a magnet field for the purpose of making the intensity of the magnetic field 1500 G or more at the intersection of the intermediate plane between the upper and lower coils, and the inner wall of the crucible. Such a range stabilizes the seeding and improves the success rate much higher.

In this way, during the seeding, the first position of the magnetic field minimum plane position of the cusp magnetic field is below the surface of the silicon melt (raw material melt) of between 30 mm to 80 mm and/or the intensity of the magnetic field at the intersection of the intermediate plane between two upper and lower coils and the inner wall of the crucible is 1500 G or more. Consequently, the magnetic field becomes in a state that affects the entire surface of the silicon melt, and the temperature variation of the silicon melt surface is decreased. Thus, the success rate of the seeding is significantly improved. Moreover, when the first position of the magnetic field minimum plane position of the cusp magnetic field is below the surface of the silicon melt of between 30 mm to 80 mm, and the intensity of the magnetic field at the intersection of the intermediate plane between two upper and lower coils and the inner wall of the crucible is 1500 G or more, then the convection-suppressing force in the silicon melt is more intensified with an increase of the intensity of the magnetic field, and the temperature variation on the silicon melt surface becomes smaller. Thus, defining an upper limit to the value of the intensity of the magnetic field during the seeding is not needed, but the upper limit of the intensity of the magnetic field can be defined according to capability and structure and the like of the apparatus (the coils forming the cusp magnetic field) and can be 5000 G or less, for example.

The seeding may be performed by a dislocation-free seeding method, which does not perform necking (Dash Necking method) after the seeding. The seed crystal with a seed crystal tip having a pointed shape is used when the dislocation-free seeding method is performed, and at this time, the angle of the tip of the seed crystal is preferably 28° or less. The seed crystal having such a shape can more effectively mitigate the heat shock generated when the silicon melt and the seed crystal comes into contact, and as a result, the success rate of dislocation-free pulling up of the silicon single crystal is further improved.

After the seeding, the necking (Dash Necking method) can be performed with the magnetic field minimum plane position unchanged and maintained at the first position. In the inventive method for producing the silicon single crystal, even when the Dash Necking method is performed, the success rate of the seeding can be stably improved, and efficient production is enabled.

### (Pulling Up of the Straight Body)

After seeding and before proceeding to pulling up the straight body, a magnetic field minimum plane position 31 on a central axis 10 of a single crystal pulling furnace 1 is moved to a second position above a first position, and the pulling up of the straight body is performed with the magnetic field minimum plane position 31 on the central axis 10 of the single crystal pulling furnace 1 at the second position. Consequently, the silicon single crystal with a low oxygen concentration and excellent in-plane distribution can be produced.

At the pulling up of the straight body, when the magnetic field minimum plane position is positioned at the first position as in the seeding, convection of a silicon melt close to a quartz crucible is suppressed thus, a relative velocity between the quartz crucible and the silicon melt increase, and then an elution of oxygen component from the quartz crucible into the silicon melt is facilitated. In order to suppress the elution of the oxygen component described above, after enlarging a diameter of the silicon single crystal, the magnetic field minimum plane position is moved to the second position above the first position before the pulling up of the straight body to produce a product portion.

In this case, the second position is preferably between 10 mm below and 100 mm above (10 mm or less downward and 100 mm or less upward) the surface of the silicon melt. In such a range, the single crystal with a low oxygen concentration and excellent in-plane distribution can be more stably produced.

When the second position of the magnetic field minimum plane position at the pulling up of the straight body of the product portion is defined between as the position 10 mm below and 100 mm above the surface from the silicon melt, the magnetic field with direction that intersects at a right angle to the melt surface can be suppressed to become too strong (close to VMCZ). Consequently, uniform boundary diffusion layer thickness at the solid-liquid interface can be maintained more stable, and high uniformity of the in-plane distribution of the oxygen concentration can be maintained.

Furthermore, the intensity of the magnetic field is preferably adjusted to a predetermined value. At the pulling up of the straight body, the intensity of the magnetic field at the intersection of the intermediate plane between the upper coil and the lower coil and the inner wall of the crucible is preferably 750 G or more and 1800 G or less. The silicon single crystal having the low oxygen concentration and excellent in-plane distribution can be more stably produced in such a range. At the pulling up of the straight body of the product portion, when the intensity of the magnetic field is 750 G or more, crystal deformation can be more efficiently suppressed, and operation can be stably continued. When the intensity is 1800 G or less, the convection of the silicon melt close to the quartz crucible is not too suppressed, and the relative velocity between the quartz crucible and the silicon melt becomes slow. This makes the oxygen component from the quartz crucible less likely to be eluted into the silicon melt and can suppress the increase of the oxygen concentration more effectively.

As described above, in the inventive method for producing the silicon single crystal, before proceeding to the pulling up of the straight body of the product portion, the second position of the magnetic field minimum plane position is preferably at the position between 10 mm below and 100 mm above the surface of the silicon melt, and/or, the intensity of the magnetic field at the intersection of the intermediate plane between two upper and lower coils and the inner wall of the crucible is preferably 750 G or more and 1800 G or less. Accordingly, the relative velocity between the quartz crucible and the silicon melt becomes slow and an effect of suppressing the elution of oxygen and an effect of facilitating the incorporation of oxygen into the single crystal from a low-oxygen layer of the surface of the silicon melt. As a result, stably realizing the low oxygen concentration lower than or equal to 3×10¹⁷ atoms/cm³ (ASTM'79) is enabled.

In the inventive method for producing the silicon single crystal, before transitioning from seeding or necking, which is a non-product portion step, to the product portion (straight body portion) step, the magnetic field minimum plane position is moved upward. The magnetic field minimum plane position may be moved upward by an upward movement of a magnetic field generator 30 using an elevating device 30c, or the magnetic field minimum plane position may be moved upward by unbalanced excitation in the result of defining the electric current values of the upper coil 30a and lower coil 30b as the electric current value of the upper coil is smaller than the electric current value of lower coil.

### EXAMPLE

Hereinafter, the present invention will be specifically described with reference to Examples. However, the present invention is not limited thereto.

Silicon raw material of 340 kg was melted in a crucible with a diameter of 32 inches (800 mm) in a CZ-pulling furnace and applied a cusp magnetic field, then a silicon single crystal with a crystal diameter of 300 mm was pulled. After pulling the single crystal, samples were sliced from positions where solidification rates were 20%, 35%, 50%, and 65%, then an in-plane distribution of an oxygen concentration was inspected using Fourier Transform Infrared (FT-IR). ROG was used as an indicator of the excellence of the in-plane distribution of oxygen concentration.

In this context, ROG was defined as a value obtained by a formula: (maximum value−minimum value)×100/maximum value, where the oxygen concentration was measured in at least two locations of a wafer center and 5 mm from a wafer periphery. In the following Examples and Comparative Examples, an average value of each position at solidification rates of 20%, 35%, 50%, and 65% was used for the ROG shown in Tables.

The following description describes a magnetic field minimum plane position as “˜ mm below/above the surface,” using a melt surface of the silicon melt (melt surface) as a reference point. Incidentally, when the description of “0 mm below the melt surface” is used, this means the surface coincides with the magnetic field minimum plane position.

### Examples 1 to 4

In Examples 1-4, silicon single crystals were produced under the below conditions.

### (Seeding)

A magnetic field minimum plane position (a position between upper and lower coils has 0 G.): 30 mm below the melt surface or 70 mm below the melt surface.

An intensity of magnetic field at an intersection of an intermediate plane between the upper coil and the lower coil and an inner wall of a crucible: 1500 G.
A crucible rotational rate: 1.0 rpm.
A single crystal rotational rate: 8 rpm.

### (Pulling Up of the Straight Body)

A magnetic field minimum plane position: 10 mm below the melt surface or 100 mm above the melt surface. An intensity of magnetic field at an intersection of an intermediate plane between the upper coil and the lower coil and an inner wall of a crucible: 1500 G
A crucible rotational rate: 1.0 rpm
A single crystal rotational rate: 8 rpm

In Examples 1 to 4, during the seeding, the magnetic field minimum plane position of a cusp magnetic field was defined as 30 mm or 70 mm below the silicon melt surface (melt surface), and the necking (Dash Necking method) was performed after the seeding. The magnetic field minimum plane position was moved upward, before transitioning to the pulling of the straight body of the product portion. Then, the magnetic field minimum plane position during the pulling of the straight body of the product portion was defined as 10 mm below or 100 mm above the silicon melt surface (melt surface). Single crystals were pulled under four different pulling conditions in total. Furthermore, a movement of the magnetic field minimum plane position was performed by using an elevating device before transitioning to the pulling of the straight body of the product portion. The results of Examples 1 to 4 are shown in Table 1.

TABLE 1

| | | | | | Product | | | | |
|---|---|---|---|---|---|---|---|---|---|
| | Seeding: | Seeding: | | Product portion: | portion: | | | | |
| | Magnetic field | Intensity of | Seeding | Magnetic field | Intensity of | Oxygen | | | |
| | minimum plane | magnetic | failure | minimum plane | magnetic | concentration | ROG | | Crystal |
| | position | field [G] | number | position [mm] | field [G] | [atoms/cm³] | [%] | Operability | Quality |
| Example1 | 30 mm below surface | 1500 | 0 | 10 mm below surface | 1500 | 2.5E17~2.7E17 | 5.2 | good | good |
| Example2 | 70 mm below surface | 1500 | 0 | 10 mm below surface | 1500 | 2.5E17~2.6E17 | 10.8 | good | good |
| Example3 | 30 mm below surface | 1500 | 0 | 100 mm above surface | 1500 | 2.7E17~2.8E17 | 11.0 | good | good |
| Example4 | 70 mm below surface | 1500 | 0 | 100 mm above surface | 1500 | 2.6E17~2.8E17 | 13.5 | good | good |

As shown in Table 1, single crystals were successfully pulled without dislocation at seeding under the conditions of Examples 1 to 4. Moreover, concerning a crystal quality of a product portion, an oxygen concentration was 3×10¹⁷ atoms/cm³ (ASTM'79) or lower, ROG was less than 15%, and an in-plane distribution with excellent distribution was obtained. The low-oxygen crystal that satisfies the required quality for a power device was successfully pulled without degrading production performance.

### Examples 5 to 8

In Examples 5 to 8, an intensity of a magnetic field at seeding was changed to 2000 G, and the intensity of the magnetic field at pulling of a straight body was changed to 1800 G. The other conditions were the same as the conditions used in Examples 1 to 4, and four pulling conditions in total were used for pulling single crystals. Results of Examples 5 to 8 are shown in Table 2.

TABLE 2

| | | | | | Product | | | | |
|---|---|---|---|---|---|---|---|---|---|
| | Seeding: | Seeding: | | Product portion: | portion: | | | | |
| | Magnetic field | Intensity of | Seeding | Magnetic field | Intensity of | Oxygen | | | |
| | minimum plane | magnetic | failure | minimum plane | magnetic | concentration | ROG | | Crystal |
| | position | field [G] | number | position [mm] | field [G] | [atoms/cm³] | [%] | Operability | Quality |
| Example5 | 30 mm below surface | 2000 | 0 | 10 mm below surface | 1800 | 2.5E17~2.8E17 | 5.1 | good | good |
| Example6 | 70 mm below surface | 2000 | 0 | 10 mm below surface | 1800 | 2.4E17~2.7E17 | 5.8 | good | good |
| Example7 | 30 mm below surface | 2000 | 0 | 100 mm above surface | 1800 | 2.6E17~2.8E17 | 10.2 | good | good |
| Example8 | 70 mm below surface | 2000 | 0 | 100 mm above surface | 1800 | 2.5E17~2.8E17 | 11.3 | good | good |

As shown in Table 2, even under the conditions of Examples 5 to 8, the pulling of the single crystals was successfully performed without dislocation at the seeding, and a quality of the crystals of a product portion had an oxygen concentration of 3×10¹⁷ atoms/cm³ (ASTM'79) or lower and ROG was less than 15%. Then, an in-plane distribution with excellent distribution was obtained. The low-oxygen crystal that satisfies the required quality for a power device was successfully pulled without degrading production performance.

### Examples 9 to 12

In Examples 9 to 12, only an intensity of the magnetic field at a pulling of a straight body of a product portion was changed to 750 G, and the other conditions were the same as in Examples 1 to 4. Single crystals were pulled under four pulling conditions in total. The results of Examples 9 to 12 are shown in Table 3.

TABLE 3

| | | | | | Product | | | | |
|---|---|---|---|---|---|---|---|---|---|
| | Seeding: | Seeding: | | Product portion: | portion: | | | | |
| | Magnetic field | Intensity of | Seeding | Magnetic field | Intensity of | Oxygen | | | |
| | minimum plane | magnetic | failure | minimum plane | magnetic | concentration | ROG | | Crystal |
| | position | field [G] | number | position [mm] | field [G] | [atoms/cm³] | [%] | Operability | Quality |
| Example 9 | 30 mm below surface | 1500 | 0 | 10 mm below surface | 750 | 2.1E17~2.3E17 | 10.2 | good | good |
| Example10 | 70 mm below surface | 1500 | 0 | 10 mm below surface | 750 | 2.2E17~2.5E17 | 10.8 | good | good |
| Example11 | 30 mm below surface | 1500 | 0 | 100 mm above surface | 750 | 2.4E17~2.6E17 | 14.5 | good | good |
| Example12 | 70 mm below surface | 1500 | 0 | 100 mm above surface | 750 | 2.4E17~2.7E17 | 14.8 | good | good |

As shown in Table 3, even under the conditions of Examples 9 to 12, the pulling of the single crystals was successfully performed without dislocation at the seeding, and a quality of the crystals of a product portion had an oxygen concentration of 3×10¹⁷ atoms/cm³ (ASTM'79) or lower and ROG was less than 15%. Then, an in-plane distribution with excellent distribution was obtained. The low-oxygen crystal that satisfies the required quality for a power device was successfully pulled without degrading production performance.

### Examples 13 and 14

In Examples 13 and 14, a dislocation-free seeding method without necking (Dash Necking method) was performed, and the other conditions were the same as in Examples 1 and Example 2. Single crystals were pulled under two pulling conditions in total. The results of Examples 13 and 14 are shown in Table 4.

TABLE 4

| | | | | | Product | | | | |
|---|---|---|---|---|---|---|---|---|---|
| | Seeding: | Seeding: | | Product portion: | portion: | | | | |
| | Magnetic field | Intensity of | Seeding | Magnetic field | Intensity of | Oxygen | | | |
| | minimum plane | magnetic | failure | minimum plane | magnetic | concentration | ROG | | Crystal |
| | position | field [G] | number | position [mm] | field [G] | [atoms/cm³] | [%] | Operability | Quality |
| Example13 | 30 mm below surface | 1500 | 0 | 10 mm below surface | 1500 | 2.4E17~2.6E17 | 5.4 | good | good |
| Example14 | 70 mm below surface | 1500 | 0 | 10 mm below surface | 1500 | 2.5E17~2.6E17 | 10.2 | good | good |

As shown in Table 4, even under the conditions of Examples 13 and 14, the pulling of the single crystals was successfully performed without dislocation at the seeding, and a quality of the crystals of a product portion had an oxygen concentration of 3×10¹⁷ atoms/cm³ (ASTM'79) or lower and ROG was less than 15%. Then, an excellent in-plane distribution was obtained. The low-oxygen crystal that satisfies the required quality for a power device was successfully pulled without degrading production performance.

### Comparative Examples 1 to 4

In Comparative Examples 1 to 4, a magnetic field minimum plane position during seeding was defined as 0 mm below the surface or 15 mm below the melt surface, an intensity of the magnetic field at the intersection of an intermediate plane between upper and lower coils and an inner wall of a crucible was defined as 1500 G or 2000 G and a condition for pulling a straight body of a product portion is the same condition for the magnetic field minimum plane position and an intensity of the magnetic field during the seeding. Four pulling conditions in total were used for pulling single crystals. Furthermore, in Comparative Examples 1 to 4, the other conditions were all the same as in Example 1. The results of Comparative Examples 1 to 4 are shown in Table 5.

TABLE 5

| | | | | | Product | | | | |
|---|---|---|---|---|---|---|---|---|---|
| | Seeding: | Seeding: | | Product portion: | portion: | | | | |
| | Magnetic field | Intensity of | Seeding | Magnetic field | Intensity of | Oxygen | | | |
| | minimum plane | magnetic | failure | minimum plane | magnetic | concentration | ROG | | Crystal |
| | position | field [G] | number | position [mm] | field [G] | [atoms/cm³] | [%] | Operability | Quality |
| Cooperative | 0 mm below surface | 1500 | 10 | 0 mm below surface | 1500 | | | poor | |
| Example1 | | | | | | | | | |
| Cooperative | 15 mm below surface | 1500 | 6 | 15 mm below surface | 1500 | 3.2E17~3.5E17 | 12.6 | fair | poor |
| Example2 | | | | | | | | | |
| Cooperative | 0 mm below surface | 2000 | 10 | 0 mm below surface | 2000 | | | poor | |
| Example3 | | | | | | | | | |
| Cooperative: | 15 mm below surface | 2000 | 5 | 15 mm below surface | 2000 | 3.5E17~3.8E17 | 9.2 | fair | poor |
| Example4 | | | | | | | | | |

As shown in Table 5, among Comparative Examples 1 to 4, Comparative Examples 1 and 3, in which a magnetic field minimum plane position was defined as 0 mm below the melt surface, failed to seed 10 times regardless of an intensity of the magnetic field thus had difficulty maintaining an operation. On the other hand, when the magnetic field minimum plane position was 15 mm below the melt surface, the number of seeding failures decreased to 6 when the intensity of the magnetic field at seeding was 1500 G (Comparative Example 2), and the number of seeding failures decreased to 5 when the intensity of the magnetic field at seeding was 2000 G (Comparative Example 4). Defining the magnetic field minimum plane position during the seeding to 15 mm below the melt surface resulted in fewer failures of the seeding than the magnetic field minimum plane position at 0 mm below the surface. However, in Comparative Examples 2 and 4, the magnetic field minimum plane position and the intensity of the magnetic field during the pulling up of the straight body of the product portion had the same condition with the seeding, an oxygen concentration of the product portion was higher than 3×10¹⁷ atoms/cm³, thus failed to pull the low-oxygen crystal that satisfies the required quality for a power device.

### Comparative Examples 5 and 6

In Comparative Examples 5 and 6, a dislocation-free seeding method without a necking (Dash Necking method) was used, and a magnetic field minimum plane position during seeding was 0 mm below the melt surface or 15 mm below the melt surface. An intensity of the magnetic field at the intersection of an intermediate plane between upper and lower coils and an inner wall of a crucible was 1500 G. The condition for pulling up of the straight body of the product portion was the same condition for the magnetic field minimum plane position and the intensity of the magnetic field during the seeding, and based on two conditions in total, pulling of single crystals were performed. Meanwhile, other conditions in Comparative Examples 5 and 6 were as all the same as conditions in Example 1. Results of Comparative Examples 5 and 6 are shown in Table 6.

TABLE 6

| | Seeding: | Seeding: | | Product portion: | Product | | | | |
|---|---|---|---|---|---|---|---|---|---|
| | Magnetic field | Intensity of | Seeding | Magnetic field | portion: | Oxygen | | | |
| | minimum plane | magnetic | failure | minimum plane | Intensity of | concentration | ROG | | Crystal |
| | position | field [G] | number | position [mm] | magnetic field [G] | [atoms/cm³] | [%] | Operability | Quality |
| Cooperative | 0 mm | 1500 | 10 | 0 mm | 1500 | | | poor | |
| Example 5 | below surface | | | below surface | | | | | |
| Cooperative | 15 mm | 1500 | 5 | 15 mm | 1500 | 3.2E17~3.4E17 | 10.4 | fair | poor |
| Example 6 | below surface | | | below surface | | | | | |

As shown in Table 6, Comparative Example 5, in which the magnetic field minimum plane position was 0 mm below the surface, failed to seed 10 times, and thus had difficulty maintaining an operation. On the other hand, in Comparative Example 6, in which the magnetic field minimum plane position was 15 mm below the surface, the number of seeding failures was decreased to 5 times. Making the magnetic field minimum plane position 15 mm below the surface at the seeding resulted in a decrease in the number of failures of the seeding compared to the magnetic field minimum plane position at 0 mm below the surface. Consequently, even in the case of a dislocation-free seeding method being performed without performing the necking (Dash Necking method) in a cusp magnetic field, it was found out that the magnetic field minimum plane position is needed to position below a surface of a silicon melt during the seeding. However, in Comparative Example 6, in which the magnetic field minimum plane position and the intensity of the magnetic field at the product portion were defined to the same condition during the seeding, an oxygen concentration of the product portion was higher than 3×10¹⁷ atoms/cm³ and thus failed to pull the low-oxygen crystal that satisfies the required quality for a power device.

As described above, according to Examples of the present invention, the single crystal with the low oxygen concentration and the excellent in-plane distribution with the improved success rate of seeding was able to be produced efficiently.

It should be noted that the present invention is not limited to the above-described embodiments. The embodiments are just examples, and any examples that have substantially the same feature and demonstrate the same functions and effects as those in the technical concept disclosed in claims of the present invention are included in the technical scope of the present invention.

1. A method for producing a silicon single crystal by a CZ method using a cusp magnetic field formed by an upper coil and a lower coil provided in a pulling furnace, the method comprising the steps of:
seeding by bringing a seed crystal into contact with a silicon melt; and
pulling up of a straight body after enlarging a diameter of the silicon single crystal, wherein
the seeding is performed with a magnetic field minimum plane position on a central axis of the pulling furnace as a first position below a surface of the silicon melt,
before proceeding to the pulling up of the straight body, the magnetic field minimum plane position on the central axis of the pulling furnace is moved to a second position above the first position,
the pulling up of the straight body is performed with the magnetic field minimum plane position on the central axis of the pulling furnace as the second position,
the first position is between 30 mm to 80 mm below the surface of the silicon melt,
the second position is between 10 mm below and 100 mm above the surface of the silicon melt,
at the seeding, an intensity of the magnetic field at an intersection of an intermediate plane between the upper coil and the lower coil and an inner wall of a crucible is 1500 G or more, and
at the pulling up of the straight body, an intensity of a magnetic field at an intersection of an intermediate plane between the upper coil and the lower coil and an inner wall of a crucible is 750 G or more and 1800 G or less.

2. The method for producing the silicon single crystal according to claim 1, wherein
the seeding is performed by a dislocation-free seeding method.

3. The method for producing the silicon single crystal according to claim 1, wherein
after the seeding, a necking is performed while the magnetic field minimum plane position on the central axis of the pulling furnace is the first position below the surface of the silicon melt.

4. The method for producing the silicon single crystal according to claim 2, wherein
after the seeding, a necking is performed while the magnetic field minimum plane position on the central axis of the pulling furnace is the first position below the surface of the silicon melt.
